(19) United States
(12) Patent Application Publication
(10) Pub. No.: US 2010/0007354 A1
(43) Pub. Date: Jan. 14, 2010

(54) System and Method for Predicting a Fault in a Power Line

(76) Inventors: Brian J. Deaver, SR., Fallston, MD (US); David G. Kreiss, San Diego, CA (US)

Correspondence Address: CAPITAL LEGAL GROUP, LLC, 1100 River Bay Road, Annapolis, MD, 21409, US

(21) Appl. No.: 12/169,223

(22) Filed: Jul. 8, 2008

(51) Int. Cl. G01R 31/02

(52) U.S. Cl. 324/539

(57) ABSTRACT

A system and method for detecting an arc of a medium voltage power line, such as an underground power line cable, is provided. In one embodiment the method comprises receiving voltage measurement data of the alternating voltage of the medium voltage power line, receiving current measurement data of the current of the medium voltage power line, detecting a current surge based on received current measurement data and upon detecting the current surge, processing the received voltage measurement data to determine whether the current surge initiated during a peak of the alternating voltage. In addition, the method may comprise transmitting a notification of the concurrent current surge. The transmission may be over the medium voltage power line, wirelessly, via fiber, via coaxial cable, or other suitable method. The current surge detection process may also comprise determining that the current surge lasts for less than a predetermined duration.

### FIELD OF THE INVENTION

The present invention generally relates to methods and apparatus for monitoring power distribution parameters, and more particularly to methods and apparatus for predicting a fault in a power line.

### BACKGROUND OF THE INVENTION

The power system infrastructure includes power lines, transformers and other devices for power generation, power transmission, and power delivery. A power source generates power, which is transmitted along high voltage (HV) power lines for long distances. Typical voltages found on HV transmission lines range from 69 kilovolts (kV) to in excess of 800 kV. The power signals are stepped down to medium voltage (MV) power signals at regional substation transformers. MV power lines carry power signals through neighborhoods and populated areas. Typical voltages found on MV power lines power range from about 1000 V to about 100 kV. The power is stepped down further to low voltage (LV) levels at distribution transformers. LV power lines typically carry power having voltages ranging from about 100 V to about 600 V to customer premises.

In some areas power lines may be buried underground. For example, underground residential distribution (URD) cables typically carry medium voltage power. The URD cable may be formed with a center conductor concentrically surrounded by an insulator, which in turn is concentrically surrounded by an outer neutral. Of concern here is that the insulation between the center conductor and outer neutral may deteriorate over time. As the insulation deteriorates, the URD cable becomes increasingly susceptible to a power line fault—an undesirable flow of electricity from the center conductor to the neutral (or other ground), which often results in a power outage.

A power line fault may sometimes be preceded by one or more brief arcs of electricity between the center conductor of the URD cable and the outer neutral. In one scenario, as the insulation deteriorates, moisture may seep into the URD cable semiconductor, effectively lowering the local resistance. As deterioration progresses, the resistance may decrease to a point where an arc occurs between the center conductor and the outer neutral through an area where moisture is present. Such current surges may further damage and shorten the useful life of the cable.

In some instances, in order to replace or repair a segment of a URD cable, it may be necessary to “turn off” the power supplied to one or more homes. While this may not be ideal, it is often more desirable than waiting for an unexpected power outage caused by a failed power line. Consequently, there is a need to be able to predict the location of imminent power line faults. These and other needs may be addressed by one or more embodiments of the present invention.

### SUMMARY OF THE INVENTION

The present invention provides a system, device, and method of detecting and alarming for the leading indicators of a power line cable failure. In one embodiment the method comprises receiving voltage measurement data of the alternating voltage of the medium voltage power line, receiving current measurement data of the current of the medium voltage power line, detecting a current surge based on received current measurement data and upon detecting the current surge, processing the received voltage measurement data to determine whether the current surge initiated during a peak of the alternating voltage. In addition, the method may comprise transmitting a notification of the concurrent current surge. The transmission may be over the medium voltage power line, wirelessly, via fiber, via coaxial cable, or other suitable method. The current surge detection process may also comprise determining that the current surge lasts for less than a predetermined duration.

The invention will be better understood by reference to the following detailed description taken in conjunction with the accompanying drawings.

### BRIEF DESCRIPTION OF THE DRAWINGS

The invention is further described in the detailed description that follows, by reference to the noted drawings by way of non-limiting illustrative embodiments of the invention, in which like reference numerals represent similar parts throughout the drawings. As should be understood, however, the invention is not limited to the precise arrangements and instrumentalities shown. In the drawings:

FIG. 1 is a block diagram of an example power line communication system, in accordance with an embodiment of the present invention;

FIG. 2 is a schematic diagram of an example configuration of a power line communication system (PLCS), in accordance with an embodiment of the present invention;

FIG. 3 is a block diagram of a portion of an example underground PLCS, in accordance with an embodiment of the present invention;

FIG. 4 is a block diagram of an example embodiment of a backhaul node;

FIG. 5 is a block diagram of an example embodiment of an access node;

FIG. 6 is a partial schematic of an example embodiment of a power line current sensor device;

FIG. 7 is a diagram of an example embodiment of a power line communication device installed at an underground transformer according to example embodiments of the present invention;

FIG. 8 is a flow chart of a method for detecting a power line arc according to example embodiments of the present invention; and

FIG. 9 is a flow chart of a method for predicting the location of a power line fault, according to an example embodiment of the present invention.

### DETAILED DESCRIPTION OF ILLUSTRATIVE EMBODIMENTS

In the following description, for purposes of explanation and not limitation, specific details are set forth, such as particular networks, communication systems, computers, terminals, devices, components, techniques, data and network protocols, power line communication systems (PLCSs), software products and systems, enterprise applications, operating systems, development interfaces, hardware, etc. in order to provide a thorough understanding of the present invention.

However, it will be apparent to one skilled in the art that the present invention may be practiced in other embodiments that depart from these specific details. Detailed descriptions of well-known networks, communication systems, computers, terminals, devices, PLCSs, components, techniques, data and network protocols, software products and systems, operating systems, development interfaces, and hardware are omitted so as not to obscure the description of the present invention.

According to an embodiment of the present invention, a power line communication and power distribution parameter measurement system monitors power distribution parameters to identify power line arcs that may be a predictor of a fault. A fault is a failure of a power line and one such type of fault may occur gradually over time due to deterioration of the insulation of a URD cable. To predict power line faults, power line current and voltage are monitored and analyzed throughout the power distribution system. In particular, specific characteristics of the power line voltage and currents (e.g., indicating an arc) may indicate the likelihood of a fault. By detecting such characteristics and the locations of the sensors making the detection, power line faults may be predicted along with a location (e.g., the segment of the power line cable predicted to fail). For example, by determining the interval between such arcs (e.g., by detecting an increase in the frequency of such arcs), the system may provide an indication of the severity of power line deterioration, and immediacy of a potential power line failure.

For an underground portion of a power distribution system, an underground residential distribution (URD) cable includes a plurality of cable segments that extend between power distribution transformers and serve as a medium voltage power line. Such URD cable is exposed to moisture. As the URD cable deteriorates, and in particular as the insulation layer deteriorates, moisture may accumulate in spots within the cable insulation. Eventually enough moisture may accumulate to lower the local resistance sufficiently that an arc occurs between the center conductor and the outer neutral (or between the center conductor and ground). A current surge occurs briefly during the arc due to the reduction in resistance. Typically, the arc occurs (is initiated) at the peak voltage (positive or negative amplitude). As the power line continues to deteriorate, more surges may occur and at a greater frequency.

The current surge accompanying the arc heats and evaporates the local moisture in the spot where the arc occurred. As a result, an arc may not repeat immediately during the next power signal cycle or for some time. Gradually, however, the moisture often builds up again until another arc and an accompanying current surge occur. Although the period between arc events may shorten during bad weather as moisture seeps into the ground, weather conditions may be factored out. As a result, the interval between arc events may be used to indicate the severity of the deterioration of a power line and the amount of time before a power line failure resulting in a power outage fault may occur. Also, as the voltage gets clipped at a lower voltage, it may be deduced that because less voltage is needed to arc the cable that the cable is getting closer to failure.

According to an embodiment of the present invention, sensors may be located in the vicinity of an access device, which generally is located in the vicinity of a distribution transformer. For example, a current sensor may monitor the current along the medium voltage power line (URD cable), and a voltage sensor may monitor the voltage of a low voltage power line. These sensors are monitored by the access device. When an arc event occurs, the current sensor may detect the current surge (a rapid and sometimes nearly, or substantially, instantaneous increase in current) and the voltage sensor may determine that the current surge occurred at the peak voltage (i.e., began arcing during the peak), which in various embodiments may be when the voltage is at the highest 20%, or more preferably, at the highest 10%. For example, the processing may detect the surge when it occurs above sixty degrees for the positive side or above (more negative than) 240 degrees on the negative side of the wave form. the seventy degrees. In yet another embodiment, the processing may use seventy degrees and 250 degrees. The arc may only extend for the duration of the peak, for some duration less than 50% of the 60 Hz period of the voltage, or may even extend a few cycles (e.g., less than ten 60 Hz cycles). In one embodiment, the processing of the data indicates an arc only when the surge is extinguished at (or before) the zero crossing. In addition, the voltage sensor may determine that the peak voltage was clipped during the surge. In a power distribution system the current flows directionally along a medium voltage power line. A current sensor positioned upstream (i.e., positionally before the location of the arc event on the URD cable) will detect the current surge, while the downstream current sensor will not detect the current surge. The voltage sensors of both upstream and downstream may detect the clipped voltage. Accordingly, the power line fault can be located to the specific URD cable between the two power distribution transformers where the current sensors are approximately located (where one current sensor detected the surge and the other did not). In some instances, the more frequently the arc event is detected, the sooner that complete failure of the URD cable is likely to occur.

Following is a description of a power line communication and power distribution parameter measurement system, including descriptions of sample embodiments of power distribution parameter sensor devices, power line communication devices, network protocols, and software. A detailed description of methods for detecting and predicting power line faults according to sample embodiments of the present invention follows thereafter.

### Communication and Measurement System

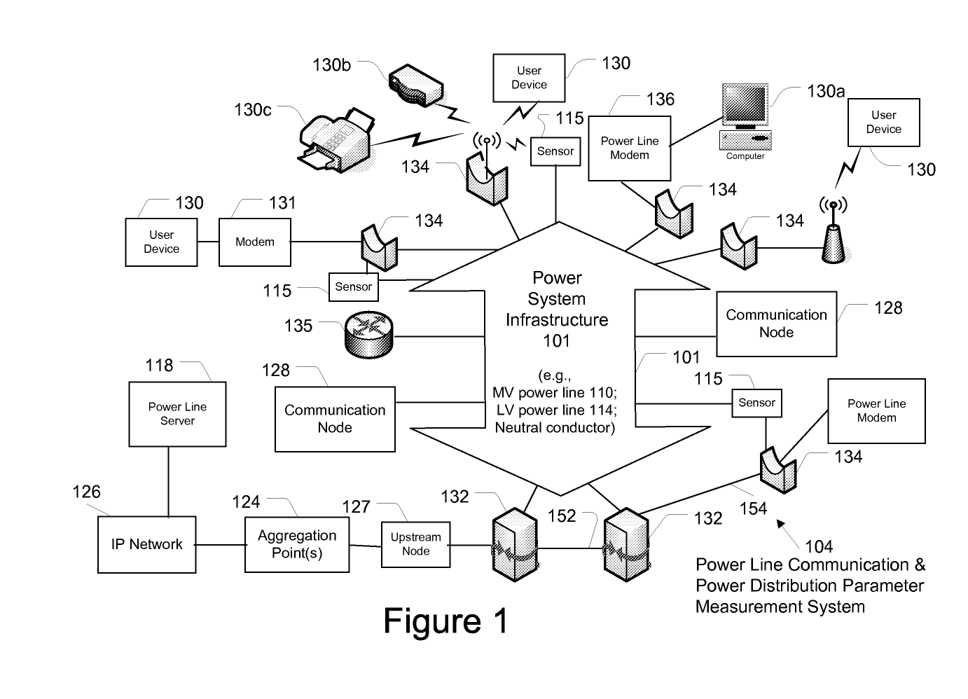

FIG. 1 shows a power line communication and power distribution parameter measurement system 104 for predicting a power line fault according to an embodiment of the present invention. Power distribution parameter data, including power line voltage and power line current, may be gathered from multiple points along a power distribution network, and transmitted to a utility or other processing center. For example, sensor devices 115 may be positioned along overhead and underground medium voltage power lines, and along network (external or internal) low voltage power lines.

The power line communication and distribution parameter measurement system 104 also may provide user services (i.e., communicate user data) and communication services to devices accessing the system. Exemplary services that may be provided include high speed broadband internet access, mobile telephone communications, broadband communications, streaming video and audio services, and other communication services. Such services may be provided to homes, buildings and other structures, and to each room, office, apartment, or other unit or sub-unit of multi-unit structures. Communication services also may be provided to mobile and stationary devices in outdoor areas such as customer premises yards, parks, stadiums, and also to public and semi-public indoor areas such as subway trains, subway stations, train stations, airports, restaurants, public and private automobiles, bodies of water (e.g., rivers, bays, inlets, etc.), building lobbies, elevators, etc.

The power line communication and power distribution parameter measurement system 104 includes a plurality of communication nodes 128 which form communication links using power lines 110, 114 and other communication media. One type of communication node 128 may be a backhaul node 132. Another type of communication node 128 may be an access node 134. Another type of communication node 128 may be a repeater node 135. A given node 128 may serve as a backhaul node 132, access node 134, and/or repeater node 135.

A communication link is formed between two communication nodes 128 over a communication medium. Some links may be formed over MV power lines 110. Some links may be formed over LV power lines 114. Other links may be gigabit-Ethernet links 152, 154 formed, for example, using a fiber optic cable. Thus, some links may be formed using a portion of the power system infrastructure 101, while other links may be formed over another communication media, (e.g., a coaxial cable, a T-1 line, a fiber optic cable, wirelessly (e.g., IEEE 802.11 a/b/g, 802.16, 1G, 2G, 3G, or satellite such as WildBlue®)). The links formed by wired or wireless media may occur at any point along a communication path between a backhaul node 132 and a user device 130.

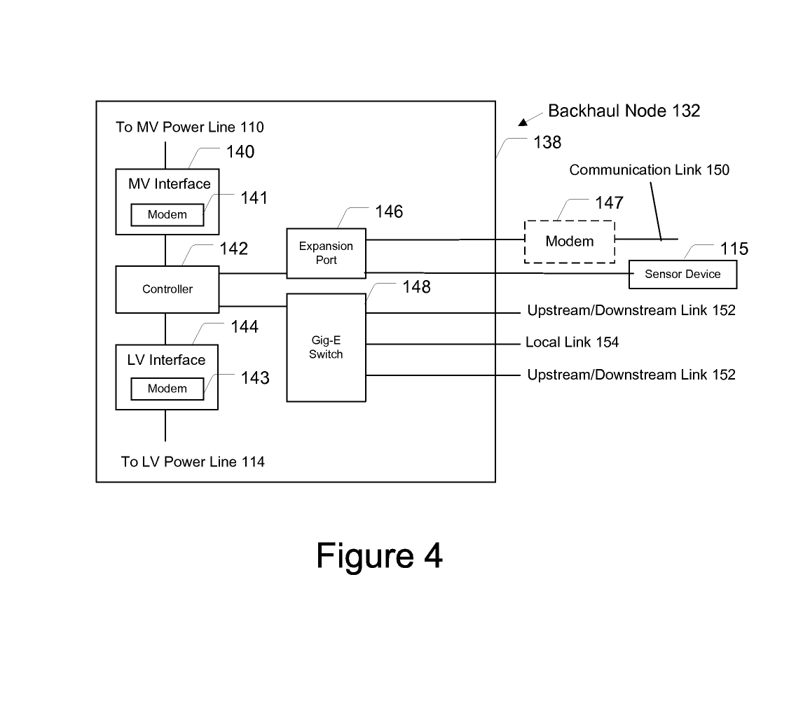

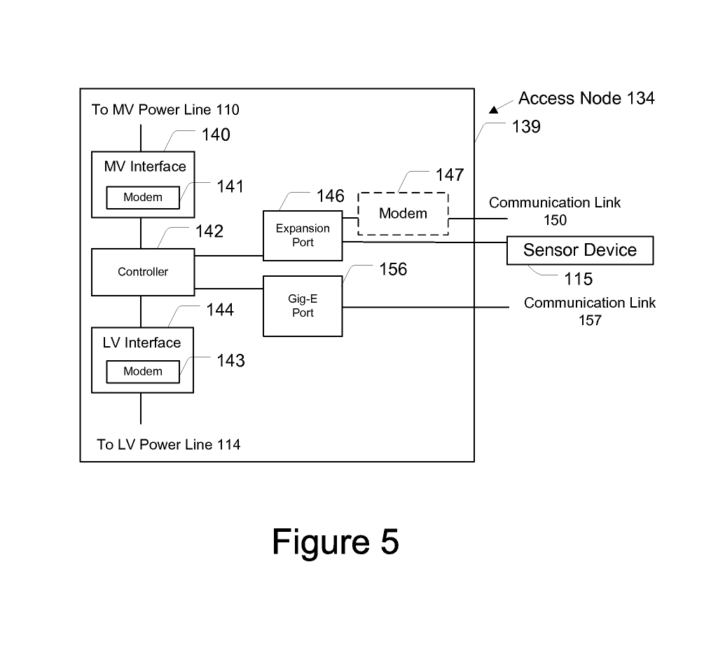

Each communication node 128 may be formed by one or more communication devices. Communication nodes which communicate over a power line medium include a power line communication device. Exemplary power line communication devices include a backhaul device 138 (see FIG. 4), an access device 139 (see FIG. 5), and a repeater. Communication nodes which access a link over a wireless medium may include a wireless access point having at least a wireless transceiver, which may comprise mobile telephone cell site/transceiver (e.g., a micro or pico cell site) or an IEEE 802.11 transceiver (Wifi). Communication nodes which access a link over a coaxial cable may include a cable modem. Communication nodes which access a link over a twisted pair may include a DSL modem. A given communication node typically will communicate in two directions (either full duplex or half duplex), which may be over the same or different types of communication media. Accordingly, a communication node 128 may include one, two or more communication devices, which may be formed along the same or different types of communication media.

A backhaul node 132 may serve as an interface between a power line medium (e.g., an MV power line 110) of the system 104 and an upstream node 127, which may be, for example, connected to an aggregation point 124 that may provide a connection to an IP network 126. The system 104 typically includes one or more backhaul nodes 132.

Upstream communications from user premises and control and monitoring communications from power line communication devices may be communicated to an access node 134, to a backhaul node 132, and then transmitted to an aggregation point 124 which is communicatively coupled to the IP network 126. Communications may traverse the IP network to a destination, such as a web server, power line server 118, or an end user device. The backhaul node 132 may be coupled to the aggregation point 124 directly or indirectly (i.e., via one or more intermediate nodes 127). The backhaul node 132 may communicate with its upstream device via any of several alternative communication media, such as a fiber optic cable (digital or analog (e.g., Wave Division Multiplexed)), coaxial cable, WiMAX, IEEE 802.11, twisted pair and/or another wired or wireless media.

Downstream communications from the IP network 126 typically are communicated through the aggregation point 124 to the backhaul node 132. The aggregation point 124 typically includes an Internet Protocol (IP) network data packet router and is connected to an IP network backbone, thereby providing access to an IP network 126 (i.e., can be connected to or form part of a point of presence or POP). Any available mechanism may be used to link the aggregation point 124 to the POP or other device (e.g., fiber optic conductors, T-carrier, Synchronous Optical Network (SONET), and wireless techniques).

An access node 134 may transmit data to and receive data from, one or more user devices 130 or other network destinations. Other data, such as power line parameter data (e.g., current measured by a power line current sensor device) may be received by an access node's power line communication device 139. The data enters the network 104 along a communication medium coupled to the access node 134. The data is routed through the network 104 to a backhaul node 132. Downstream data is sent through the network 104 to a user device 130. Exemplary user devices 130 include a computer 130a, LAN, a WLAN, router 130b, Voice-over IP endpoint, game system, personal digital assistant (PDA), mobile telephone, digital cable box, security system, alarm system (e.g., fire, smoke, carbon dioxide, security/burglar, etc.), stereo system, television, fax machine 130c, HomePlug residential network, or other user device having a data interface. The system also may be use to communicate utility usage data from a automated gas, water, and/or electric power meter. A user device 130 may include or be coupled to a modem to communicate with a given access node 134. Exemplary modems include a power line modem 136, a wireless modem 131, a cable modem, a DSL modem or other suitable modem or transceiver for communicating with its access node.

A repeater node 135 may receive and re-transmit data (i.e., repeat), for example, to extend the communications range of other communication elements. As a communication traverses the communication network 104, backhaul nodes 132 and access nodes 134 also may serve as repeater nodes 135, (e.g., for other access nodes and other backhaul nodes 132). Repeaters may also be stand-alone devices without additional functionality. Repeaters 135 may be coupled to and repeat data on MV power lines or LV power lines (and, for the latter, be coupled to the internal or external LV power lines).

Various user devices 130 and power line communication devices (PLCD) may transmit and receive data over the communication links to communicate via an IP network 126 (e.g., the Internet). Communications may include measurement data of power distribution parameters, control data and user data. For example, power line parameter data and control data may be communicated to a power line server 118 for processing. A power line parameter sensor device 115 may be located in the vicinity of, and communicatively coupled to, a power line communication device 135, 138, 139 to measure or detect power line parameter data.

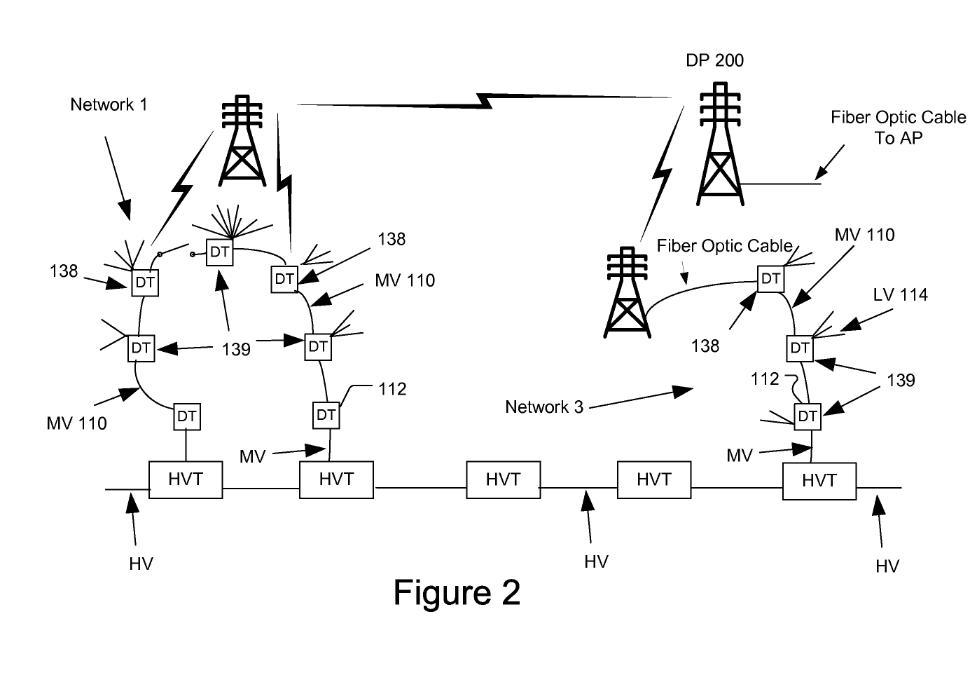

FIG. 2 illustrates a power distribution and communication system configuration that may employ an embodiment of the present invention. High voltage power lines extend between high voltage transformers HVT. Various regional sub-networks may branch from the HVTs with medium voltage power lines extending through neighborhoods and other areas. In a given embodiment such as shown in FIG. 2, the sub-networks may include underground URD MV cables 110 extending between distribution transformers 112. In FIG. 2 two underground networks are depicted with distribution transformers labeled DT. Sub-network 1 (on the left) includes seven distribution transformers. Network 3 (on the right) includes three distribution transformers. Referring to network 1, backhaul devices 138 are located at two distribution transformers 112 and an access device 139 is installed at the remaining distribution transformers 112. Referring to network 3, access devices 139 are located at two distribution transformers 112 and a backhaul device 138 is located at the other distribution transformer. Each access device 139 is configured to communicate with a backhaul device 138 of its own network. For ease of illustration, in FIG. 2 the backhaul devices 138 and access devices 139 are not shown separately from the distribution transformers 112.

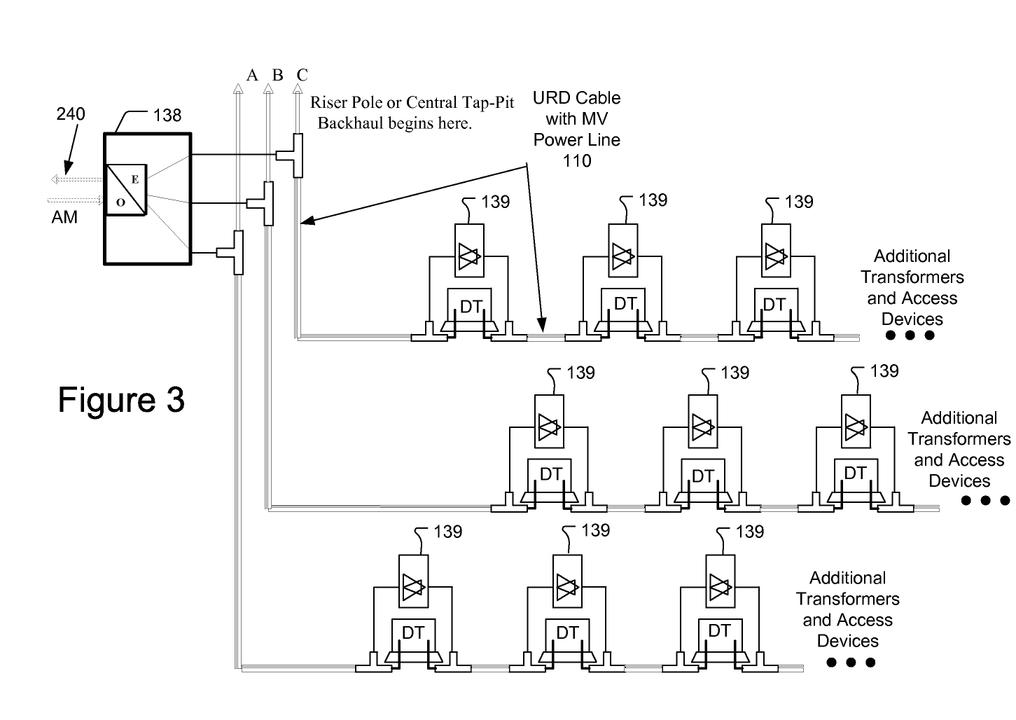

FIG. 3 shows a portion of underground network having three URD power lines—each composed of multiple segments. A backhaul device 138 is coupled to the three cables and serves the access devices 139 located along the various URD cables. Each URD power lines which extend to multiple distribution transformers 112. An access device 139 is shown at each distribution transformer 112. Each access device 139 is communicatively coupled to an MV power line 110 (i.e., URD cable) and to one or more LV power lines 114 (not shown in this figure). The access device 139 may communicate with the backhaul device 138 directly, or alternatively, data from the access device 139 may be repeated (e.g., demodulated, source decoded, channel decoded, error decoded, decrypted and then encrypted, error encoded, channel encoded, source encoded and modulated) and/or amplified by one or more of the other access devices 139 located between the access device 139 and the backhaul device 138.

The access devices 139 communicate with user devices in the customer premises via the low voltage power lines or, alternately, via a wireless link. The access device 139 typically transmits data received from the customer premises to the backhaul device 138 which in turn, transmits the data to an aggregation point (see FIG. 1).

### Backhaul Device 138:

Communication nodes, such as access nodes, repeaters, and other backhaul nodes, may communicate to and from the IP network (which may include the Internet) via a backhaul node 132. In one example embodiment, a backhaul node 132 comprises a backhaul device 138. The backhaul device 138, for example, may transmit communications directly to an aggregation point 124, or to a distribution point 127 which in turn transmits the data to an aggregation point 124. Detailed descriptions of exemplary power line communication devices are described below.

FIG. 4 shows an example embodiment of a backhaul device 138 which may form all or part of a backhaul node 132. The backhaul device 138 may include a medium voltage power line interface (MV Interface) 140, a controller 142, an expansion port 146, and a gigabit Ethernet (gig-E) switch 148. In some embodiments the backhaul device 138 also may include a low voltage power line interface (LV interface) 144. The MV interface 140 is used to communicate over the MV power lines and may include an MV power line coupler coupled to an MV signal conditioner, which may be coupled to an MV modem 141. The MV power line coupler prevents the medium voltage power from passing from the MV power line 110 to the rest of the device's circuitry, while allowing the communications signal to pass between the backhaul device 138 and the MV power line 110. The MV signal conditioner may provide amplification, filtering, frequency translation, and transient voltage protection of data signals communicated over the MV power lines 110. Thus, the MV signal conditioner may be formed by a filter, amplifier, a mixer and local oscillator, and other circuits which provide transient voltage protection. The MV modem 141 may demodulate, decrypt, and decode data signals received from the MV signal conditioner and may encode, encrypt, and modulate data signals to be provided to the MV signal conditioner.

The backhaul device 138 also may include a low voltage power line interface (LV Interface) 144 for receiving and transmitting data over an LV power line 114. The LV interface 144 may include an LV power line coupler coupled to an LV signal conditioner, which may be coupled to an LV modem 143. In one embodiment the LV power line coupler may be an inductive coupler. In another embodiment the LV power line coupler may be a conductive coupler. The LV signal conditioner may provide amplification, filtering, frequency translation, and transient voltage protection of data signals communicated over the LV power lines 114. Data signals received by the LV signal conditioner may be provided to the LV modem 143. Thus, data signals from the LV modem 143 are transmitted over the LV power lines 110 through the signal conditioner and coupler. The LV signal conditioner may be formed by a filter, amplifier, a mixer and local oscillator, and other circuits which provide transient voltage protection. The LV modem 143 may demodulate, decrypt, and decode data signals received from the LV signal conditioner and may encode, encrypt, and modulate data signals to be provided to the LV signal conditioner.

The backhaul device 138 also may include an expansion port 146, which may be used to connect to a variety of devices. For example a wireless access point, which may include a wireless transceiver or modem 147, may be integral to or coupled to the backhaul device 138 via the expansion port 146. The wireless modem 147 may establish and maintain a communication link 150. In other embodiments a communication link is established and maintained over an alternative communications medium (e.g., fiber optic, cable, twisted pair) using an alternative transceiver device. In such other embodiments the expansion port 146 may provide an Ethernet connection allowing communications with various devices over optical fiber, coaxial cable or other wired medium. In such embodiment the modem 147 may be an Ethernet transceiver (fiber or copper) or other suitable modem may be employed (e.g., cable modem, DSL modem). In other embodiments, the expansion port may be coupled to a Wifi access point (IEEE 802.11 transceiver), WiMAX (IEEE 802.16), or mobile telephone cell site. The expansion port may be employed to establish a communication link 150 between the backhaul device 138 and devices at a residence, building, other structure, another fixed location, or between the backhaul device 138 and a mobile device.

Various sensor devices 115 also may be connected to the backhaul device 138 through the expansion port 146 or via other means (e.g., a dedicated sensor device interface not shown). Exemplary sensors that may form part of a power distribution parameter sensor device 115 and be coupled to the backhaul device 138 may include, a current sensor, voltage sensor, a level sensor (to determine pole tilt), a camera (e.g., for monitoring security, detecting motion, monitoring children's areas, monitoring a pet area), an audio input device (e.g., microphone for monitoring children, detecting noises), a vibration sensor, a motion sensor (e.g., an infrared motion sensor for security), a home security system, a smoke detector, a heat detector, a carbon monoxide detector, a natural gas detector, a thermometer, a barometer, a biohazard detector, a water or moisture sensor, a temperature sensor, and a light sensor.

The expansion port may provide direct access to the core processor (which may form part of the controller 142) through a MII (Media Independent Interface), parallel, serial, or other connection. This direct processor interface may then be used to provide processing services and control to devices connected via the expansion port thereby allowing for a more less expensive device (e.g., sensor). The backhaul device 138 may include multiple sensor devices 115 so that parameters of multiple power lines may be measured. For example, separate parameter sensor devices 115 may be located at each of three MV power line conductors, while other parameter sensor devices may be located on each of two energized LV power line conductors, and still other sensor devices may be located on each neutral conductor. One skilled in the art will appreciate that other types of utility data also may be gathered. As will be evident to those skilled in the art, the expansion port may be coupled to an interface for communicating with the interface of the sensor device 116 via a non-conductive communication link.

The backhaul device 138 also may include a gigabit Ethernet (Gig-E) switch 148. Gigabit Ethernet is a term describing various technologies for implementing Ethernet networking at a nominal speed of one gigabit per second, as defined by the IEEE 802.3z and 802.3ab standards. There are a number of different physical layer standards for implementing gigabit Ethernet using optical fiber, twisted pair cable, or balanced copper cable. In 2002, the IEEE ratified a 10 Gigabit Ethernet standard which provides data rates at 10 gigabits per second. The 10 gigabit Ethernet standard encompasses seven different media types for LAN, MAN and WAN. Accordingly the gig-E switch may be rated at 1 gigabit per second (or greater as for a 10 gigabit Ethernet switch).

The switch 148 may be included in the same housing or co-located with the other components of the node (e.g., mounted at or near the same utility pole or transformer). The gig-E switch 148 maintains a table of which communication devices are connected to which switch 148 port (e.g., based on MAC address). When a communication device transmits a data packet, the switch receiving the packet determines the data packet's destination address and forwards the packet towards the destination device rather than to every device in a given network. This greatly increases the potential speed of the network because collisions are substantially reduced or eliminated, and multiple communications may occur simultaneously.

The backhaul device 138 also may include a controller 142 which controls the operation of the device 138 by executing program codes stored in memory. In addition, the program code may be executable to process the measured parameter data to, for example, convert the measured data to current, voltage, or power factor data. The backhaul 138 may also include a router, which routes data along an appropriate path. In this example embodiment, the controller 142 includes program code for performing routing (hereinafter also to include switching and/or bridging). Thus, the controller 142 may maintain a table of which communication devices are connected to port in memory. The controller 142, of this embodiment, matches data packets with specific messages (e.g., control messages) and destinations, performs traffic control functions, performs usage tracking functions, authorizing functions, throughput control functions and similar related services. Communications entering the backhaul device 138 from the MV power lines 110 at the MV interface 140 are received, and then may be routed to the LV interface 144, expansion port 146 or gig-E switch 148. Communications entering the backhaul device 138 from the LV power lines 114 at the LV interface 144 are received, and may then be routed to the MV interface 140, the expansion port 146, or the gig-E switch 148. Communications entering the backhaul device 138 from the expansion port 146 are received, and may then be routed to the MV interface 140, the LV interface 144, or the gig-E switch 148. Accordingly, the controller 142 may receive data from the MV interface 140, LV interface 144 or the expansion port 146, and may route the received data to the MV interface 140, LV interface 144, the expansion port 146, or gig-E switch 148. In this example embodiment, user data may be routed based on the destination address of the packet (e.g., the IP destination address). Not all data packets, of course, are routed. Some packets received may not have a destination address for which the particular backhaul device 138 routes data packets. Additionally, some data packets may be addressed to the backhaul device 138. In such case the backhaul device may process the data as a control message.

### Access Device 139:

The backhaul nodes 132 may communicate with user devices via one or more access nodes 134, which may include an access device 139. FIG. 5 shows an example embodiment of such an access device 139 for providing communication services to mobile devices and to user devices at a residence, building, and other locations.

In one example embodiment, access nodes 124 provide communication services for user devices 130 such as security management; IP network protocol (IP) packet routing; data filtering; access control; service level monitoring; service level management; signal processing; and modulation/demodulation of signals transmitted over the communication medium.

The access device 139 of this example node 134 may include a bypass device that moves data between an MV power line 110 and an LV power line 114. The access device 139 may include a medium voltage power line interface (MV Interface) 140 having a MV modem 141, a controller 142, a low voltage power line interface (LV interface) 144 having a LV modem 143, and an expansion port 146, which may have the functionality, functional components (and for connecting to devices, such as power line parameter sensor device 115) as previously described above with regard of the backhaul device 138. The access device 139 also may include a gigabit Ethernet (gig-E) port 156. The gig-E port 156 maintains a connection using a gigabit Ethernet protocol as described above for the gig-E switch 148 of FIG. 4. The power parameter sensor device 116 may be connected to the access device 139 to measure and/or detect one or more parameters of the MV power or the LV power line, which, for example, may include power line voltage, power line current, power usage, detection of a power outage, detection of water in a pad mount, detection of an open pad mount, detection of a street light failure, power delivered to a transformer, power factor data (e.g., the phase angle between the voltage and current of a power line), power delivered to a downstream branch, the harmonic components of a power signal, load transients, and/or load distribution. In addition, the access device 134 may include multiple sensor devices 116 so that parameters of multiple power lines may be measured such as a separate parameter sensor device 116 on each of three MV power line conductors (when available) and a separate parameter sensor device on each of two energized LV power line conductors and one on each neutral conductor. One skilled in the art will appreciate that other types of utility data also may be gathered. The sensor devices 115 described herein may be co-located with the power line communication device with which the sensor device 115 communicates or may be displaced from such device (e.g., at the next utility pole or transformer).

The Gig-E port 156 may maintain an Ethernet connection for communicating with various devices over optical fiber, coaxial cable or other wired medium. For example, a communication link 157 may be maintained between the access device 139 and another device through the gig-E port 156. For example, the gig-E port 156 may provide a connection to user devices 130, sensor devices (as described above with regard to the expansion port 146, such as to power line parameter sensor device 115), or a cell station 155.

Communications may be received at the access device 139 through the MV interface 140, LV interface 144, expansion port 146 or gig-E port 156. Communications may enter the access device 139 from the MV power lines 110 through the MV interface 140, and then may be routed to the LV interface 142, expansion port 146 or gig-E port 156. Communications may enter the access device 139 from the LV power lines 114 through the LV interface 144, and then may be routed to the MV interface 140, the expansion port 146, or the gig-E port 156. Communications may enter the access device 139 from the expansion port 146, and then may routed to the MV interface 140, the LV interface 144, or the gig-E port 156. Communications may enter the access device 139 via the gig-E port 156, and then may be routed to the MV interface 140, the LV interface 144, or the expansion port 146. The controller 142 controls communications through the access device 139. Accordingly, the access device 139 receives data from the MV interface 140, LV interface 144, the expansion port 146, or the gig-E port 156 and may route the data to the MV interface 140, LV interface 144, expansion port 146, or gig-E port 156 under the direction of the controller 142. In one example embodiment, the access node 134 may be coupled to a backhaul node 132 via a wired medium coupled to Gig-E port 156 while in another embodiment, the access node is coupled to the backhaul node 132 via an MV power line (via MV interface 140). In yet another embodiment, the access node 134 may be coupled to a backhaul node 132 via a wireless link (via expansion port 146 or Gig-E port 156). In addition, the controller may include program code that is executable to control the operation of the device 139 and to process the measured parameter data to, for example, convert the measured data to current, voltage, or power factor data.

### Other Devices:

Another communication device is a repeater (e.g., indoor, outdoor, low voltage (LVR) and/or medium voltage) which may form part of a repeater node 135 (see FIG. 1). A repeater serves to extend the communication range of other communication elements (e.g., access devices, backhaul devices, and other nodes). The repeater may be coupled to power lines (e.g., MV power line; LV power line) and other communication media (e.g., fiber optical cable, coaxial cable, T-1 line or wireless medium). Note that in some embodiments, a repeater node 135 may also include a device for providing communications to a user device 130 (and thus also serve as an access node 134).

In various embodiments a user device 130 is coupled to an access node 134 using a modem. For a power line medium, a power line modem 136 is used. For a wireless medium, a wireless modem is used. For a coaxial cable, a cable modem is may be used. For a twisted pair, a DSL modem may be used. The specific type of modem depends on the type of medium linking the access node 134 and user device 130.

In addition, the PLCS may include intelligent power meters, which, in addition to measuring power usage, may include a parameter sensor device 115 and also have communication capabilities (a controller coupled to a modem coupled to the LV power line) for communicating the measured parameter data to the access node 134. Detailed descriptions of some examples of such power meter modules are provided in U.S. patent application Ser. No. 11/341,646, filed on Jan. 30, 2006 entitled, “Power Line Communications Module and Method,” which is hereby incorporated herein by reference in it entirety.

A power line modem 136 couples a communication to or from an LV power line 114. A power line modem 136 is coupled on one side to the LV power line. On the other side, the power line modem 136 connects to communication device via a wired or wireless medium. One protocol for communicating with access nodes 132 over an LV power line is the HomePlug 1.0 standard of the HomePlug® Alliance for communications over low voltage power lines. In this manner, a customer can connect a variety of user devices 130 to the communication network 104.

Some examples of a power line communications systems and devices are provided in U.S. Pat. No. 7,321,291, issued Jan. 22, 2008, entitled “Power Line Communications System and method of Operating the Same” and U.S. patent application Ser. No. 11/389,063, filed Jan. Mar. 27, 2006, entitled “Underground Power Line Communication System and Method,” each of which is incorporated herein by reference in its entirety.

### Power Distribution Parameter Sensor Device:

In some embodiments, one or more power line parameter sensor devices 115 may be installed at various communication nodes 128 to measure power line parameters of various regions, neighborhoods and structures. The power line distribution parameter sensor device 115 may measure or detect a power distribution parameter, such as LV or MV power line voltage and current (e.g., real time and/or RMS). One skilled in the art will appreciate that other types of parameter data also may be measured and detected. The power distribution parameter may be sampled by the power line communication device and communicated to a power line server 118, or other power line distribution management system and/or power line communication management system.

One sensor device 115 may be configured to provide data of more than one parameter. For example, a sensor device 115 may be configured to provide data of the voltage and current carried by the power line (and therefore have multiple sensor devices). One or more sensor devices 115 may be installed at a given power line 110 and/or 114 and be coupled to a corresponding power line communication device 138, 139, 135. For example, a power line current sensor device may be installed at power lines 110 and 114 alone or with another power line parameter sensor device (e.g., a power line voltage sensor device). Such a configuration may be used to determine the current and power into and out of a transformer. In addition, the data provided by the sensor device 115 may be used to determine additional parameters (either by the sensor device, the power line communication device, or a remote computer). For example, a sensor device 115 may be configured to measure the instantaneous voltage and current (e.g., over brief time period). The measurement data may be provided to the power line communication device (e.g., backhaul device 138, access device 139, or repeater 135 collectively referred to herein as a PLCD 137) for processing. With adequate voltage and current sampling, the device 137 may compute the power factor of the power line (through means well known in the art). Thus, other power line parameters may be measured using an appropriate sensor device coupled to a power line 110, 114 in the vicinity of a power line communication device 137 in place of, or in addition to, the power line current sensor device.

In an example embodiment, the sensor device 115 may comprise a power line current sensor device that is formed of a Rogowski coil and such sensor device may be installed throughout a network (on both MV and LV power lines). The Rogowski coil is an electrical device for measuring alternating current (AC) or high speed current pulses. An exemplary embodiment includes a first and second helical coils of wire (loops) electrically connected in series with each other. The first loop is wound with a substantially constant winding density in a first direction around a core that has a substantially constant cross section. The second loop is wound with a substantially constant winding density in a second direction around a core that has a substantially constant cross section. A conductor (e.g., a power line) whose current is to be measured traverses through the loops. A voltage may be induced in the coil based on the rate of change of the current running through the power line. Rogowski coils may have other configurations as well. Some examples of a sensor devices are described in U.S. patent application Ser. No. 11/555,740 filed Nov. 2, 2006 “Power Line Communication and Power Distribution Parameter Measurement System and Method,” which is incorporated herein by reference in its entirety.

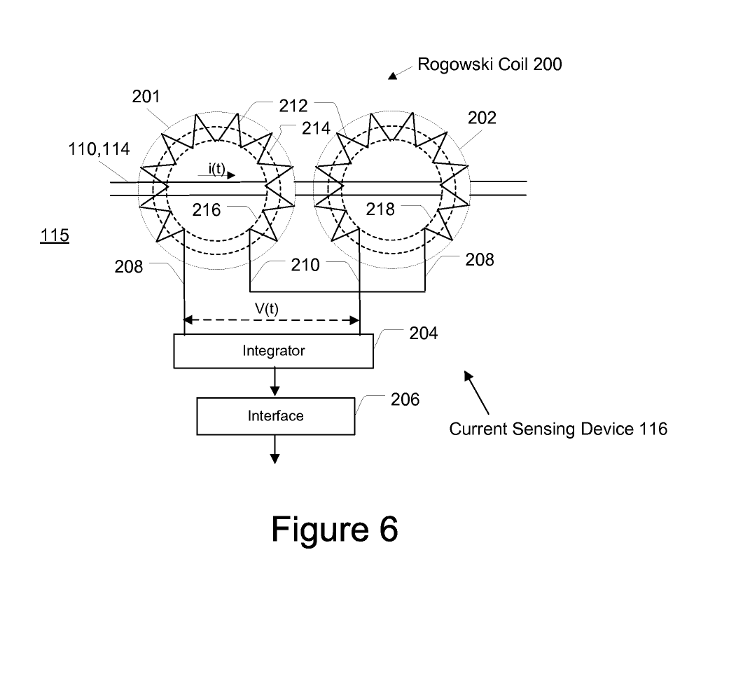

FIG. 6 shows one example embodiment of a power line parameter sensor device 115, which comprises a power line current sensor device 116 including a Rogowski coil 200 having two loops 201, 202, an integrator 204 and an interface 206. Each loop 201, 202 has a first end 208 and a second end 210. By shaping the loops 201, 202 to bring the two ends 208, 210 toward each other, while leaving space between the ends 208, 210, the Rogowski coil 200 may be readily installed at a power line 110, 114. The coil 200 may have a generally circular shape with an open arc between the ends 208, 210 (to be slipped around the power line) or may be substantially a full closed circle (and formed in two pieces that are hinged together to clamp over the power line). One of ordinary skill in the art will appreciate that other shapes may be implemented. In this example embodiment, to install the current sensor device 116, the two pieces of the loops 201, 202 are clamped around the power line 110, 114 (which may require pulling back the power line neutral conductor for underground power lines). A power line 110, 114 passes through the circular shape as shown. An advantage of these configurations is that the power line 110, 114 may not need to be disconnected (in many instances) to install the current sensor device 116.

The coil 200 of the Rogowski coil may include a first winding 201 wound in a first direction, a second winding 202 wound in a second direction, and wherein said first winding 201 and said second winding 202 each include traces on a printed circuit board. In some embodiments the windings 201, 202 are traced on one or more printed circuit boards (PCBs) 216, 218, and then the printed circuit boards (if more than one) are coupled together to form a monolithic PCB assembly (i.e., one structure). In another embodiment, the two windings of the coil are traced together and interwoven with each other on the PCB (a multi-layer printed circuit board) and therefore may be referred to as being “coupled” together. Because the windings are traced within each other (that is, the loops are interwoven), the loops are not identical in form. In another embodiment, the windings may be traced separately on separate PCBs and have identical geometries on separate PCBs, and be positioned along the power line 110, 114 in close proximity.

As alternating current flows through the power line 110, 114, a magnetic field is generated inducing an electrical field (i.e. voltage) within each winding 201, 202 of the Rogowski coil 200. However, other sources of electromagnetic interference also may induce current flow in the windings 201, 202. By including a left-hand winding 201 and a right-hand winding 202 (i.e., windings in substantially opposite directions) with equally spaced windings, the effects from external sources are largely cancelled out. In particular, external fields from sources outside the Rogowski coil 200, such as other power lines or power line communication and distribution equipment, generate equal but opposite electrical flow in the windings 201, 202. The Rogowski coil 200 provides an instantaneous voltage measurement that is related to the alternating current (AC) flowing through the power line 110, 114.

Each winding 201, 202 of the Rogowski coil 200 comprises an electrical conductor 212 wound around a dielectric core 214 (e.g., PCB). In an example embodiment each loop 201, 202 has windings that are wound with a substantially constant density and a core 214 that has a magnetic permeability that may be equal to the permeability of free space μₒ (such as, for example, air) or a printed circuit board. In addition, the cross section of the core 214 may be substantially constant.

To obtain an expression for the voltage that is proportional to the current flowing through the power line 110, 114, the coil output voltage, v(t), may be integrated. For example, the integrator 204 may convert the measured voltage v(t) into a value equating to measured current. In example embodiments, the integrator 204 may comprise a resistor-capacitor (RC) integrator, an operational amplifier integrator, a digital filter (integrator), another circuit or a processor. Observing that the voltage v(t), is proportional to the derivative of the current being measured, and that if that current is sinusoidal, the voltage v(t) will also be sinusoidal. Thus, determining the current does not always require integration of the voltage v(t)), in which embodiment the integrator 204 may be omitted.

Each power line distribution parameter sensor device 115 may include an interface 206 which provides communications with a power line communication device, such as a backhaul device 138, an access device 139, a repeater 135, or other communication device. In various embodiments different interfaces 206 may be implemented. In some embodiments the sensor device 115 may include an analog to digital converter (ADC). In other embodiments, raw analog data is communicated from the sensor device 115 to the power line communication device, which may convert the analog data to digital data (via an ADC) and provide processing. Such processing may include, for example, time stamping, formatting the data, normalizing the data, converting the data (e.g., converting the voltage measured by the ADC to a current value), removing an offset, and other such data processing. The processing also may be performed in the sensor device 115, in the power line communication device. Thus, the sensor device 115 of some embodiments may include a controller, an analog to digital converter (ADC), and a memory coupled to said ADC (perhaps via a controller) and configured to store current data. Alternately, the data may be transmitted to the power line server 118 or another remote computer for processing.

Various manners of coupling the power line parameter sensor device 115 to the power line communication device 138, 139, 135 may be achieved via a non-conductive communication link to provide electrical isolation (when necessary) from the medium voltage power line 110. In various embodiments, a wired medium, a fiber optic cable or other medium that does not conduct high voltages may be used. For example, the power line communication device 138, 139, 135 each may include a fiber optic transceiver (or fiber optic transmitter in the sensor device 115 and an optic receiver in the communication device). The fiber optic cable may carry analog or digitized sensor data to the power line communication device 138, 139, 135.

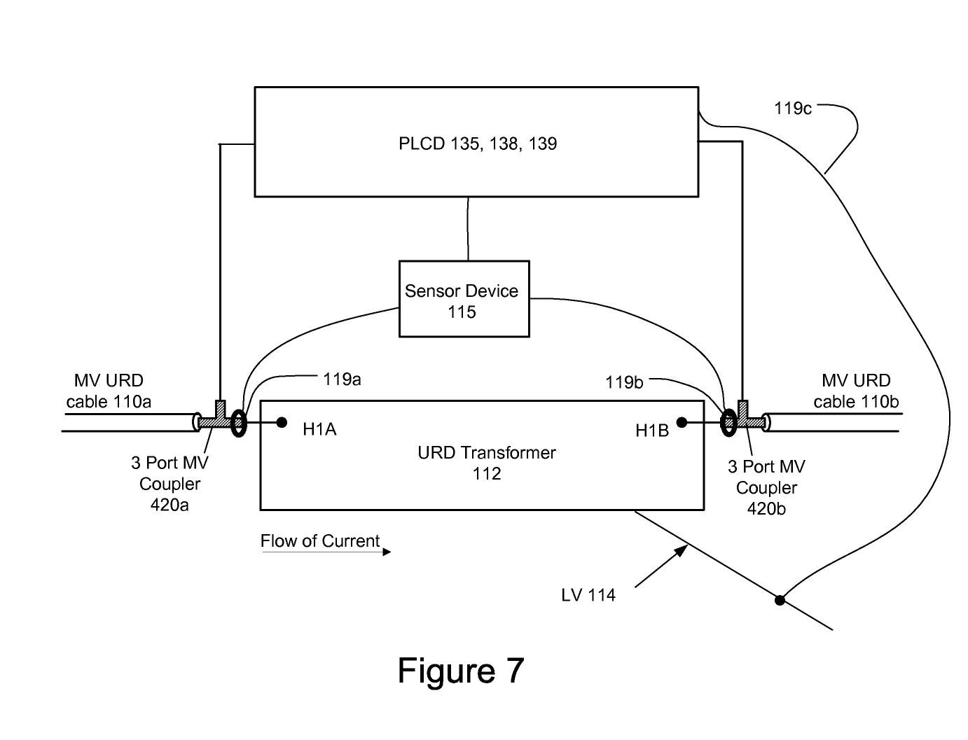

FIG. 7 illustrates an example configuration for positioning a sensor device 115 for use with underground residential distribution (URD) transformers. As illustrated, URD transformers 112 are configured differently from overhead transformers as there is no tap conductor connecting the MV power line 110 to the transformer 112. More specifically, the URD cable is connected to two terminals (H1A and H1B) of the transformer and the current flows “through” the transformer as shown. In this embodiment, the power line communication device (PLCD—e.g., backhaul device 138, access device 139, repeater 135 collectively referred to herein as a PLCD 137) is a three port device that is connected to the upstream MV power line segment 110a (which may be connected to an upstream transformer) via coupler 420a, the downstream MV power line segment 110b (which may be connected to a downstream transformer) via coupler 420b, and to the LV power line 114 for communication with devices in one or more customer premises. In this embodiment sensor 119a is coupled to upstream MV power line segment 110a and sensor 119b is coupled to the downstream MV power segment 110b. Similar to other configurations described herein, measuring the current before (sensor 119a) and after (sensor 119b) the transformer 112 allows one to determine the current provided to the transformer 112 to thereby detect an overload condition or other condition. Both sensors 119 are connected to the sensor device 115, which itself is connected to the PLCD. In addition, a wire 119c connects the PLCD 137 to the LV power line for communications over the LV power line 114. In addition, the PLCD 137 may include a voltage sensor in its housing that measures the voltage of the LV power line that is conducted up the wire 119c. In practice the PLCD 137 may be electrically connected to two LV energized connectors for communications and to measure their respective voltages.

It is worth noting that URD power lines are insulated power lines and the sensors 119 (which may include, for example, a Rogowski coil or other sensor) may be disposed around (external to) the insulation of the power line at a location where the external neutral of the power line has been removed or pealed away. In this embodiment, the current sensors 119 may be integrated with or mounted beside (and be separate from) the couplers 420. While the sensors 119 are shown on the transformer side of the couplers 420, they could be mounted on the opposite side of the couplers as well. While the sensor device 115 is shown separately from the PLCD, this configuration may be more suitable for combining the sensor device 115 and its circuitry with (e.g., in the same housing) as the PLCD circuitry. This is because there is no need to isolate the sensor device 115 from the PLCD, because the sensor device 115 is not exposed to MV voltages (because the MV URD cable is insulated).

For each of the configurations, a voltage sensor device also may be installed to measure power line voltage. Such voltage sensor device may be located in the vicinity of (or integrated with) the current sensor device 116 of the sensor device 115 (e.g., if it is feasible to measure the MV voltage). In one example embodiment, a voltage sensor is connected to the LV power line. Depending on the embodiment a single voltage sensor may be connected to either energized conductor or a multiple voltage sensors may be configured to measure the voltage of each energized LV conductor (typically two or three). The voltage sensors may be physically disposed within the housing of the PLCD (or a separate housing) and be connected to the LV power line 114 through the one or more conductor leads that connect the PLCD 138, 139, 135 to the LV power line for receiving power and for communicating over the LV power line. By knowing the LV voltage, the MV voltage may be computed based on the turns ratio of the transformer 112 (which may be stored in memory of the PLCD 137 or the PLS 118).

In other embodiments the voltage sensor device may be more remote. Voltage along the MV power line may be assumed to be generally the same across a given MV section or may be estimated at various transformer 112 based on measurements at a MV substation. Accordingly, a voltage sensor device may not be necessary at the parameter sensor device 115 in all embodiments and in some embodiments may be remote (e.g., such as on the MV power line, at the MV substation). In some embodiments, voltage data (whether estimated or derived from such voltage sensor device), may be associated with measurements of the power line current obtained from the various sensor devices 115b,c located in the vicinity of each respective transformer 112. The power line voltage and associated power line current may be used to calculate or estimate an equivalent load for the power supplied by each transformer 112b,c.

In one example embodiment, the PLCD 137 is connected to at least one current sensor 119 that is configured to measure the current of the MV power line. In addition, in some such embodiments, the PLCD 137 includes or is connected to one voltage sensor configured to measure the voltage of the LV power line 114 in order to detect the peak MV voltage and, in some instances, detect of clip of the peak MV voltage.

### Network Communication Protocols:

The communication network 104 (see FIG. 1) may provide high speed internet access and other high data-rate data services to user devices, homes, buildings and other structure, and to each room, office, apartment, or other unit or sub-unit of multi-unit structure. In doing so, a communication link is formed between two communication nodes 128 over a communication medium. Some links are formed by using a portion 101 of the power system infrastructure. Specifically, some links are formed over MV power lines 110, and other links are formed over LV power lines 114. Still other links may be formed over another communication media, (e.g., a coaxial cable, a T-1 line, a fiber optic cable, wirelessly (e.g., IEEE 802.11 a/b/g, 802.16, 1G, 2G, 3G, or satellite such as WildBlue®)). Some links may comprise wired Ethernet, multipoint microwave distribution system (MMDS) standards, DOCSIS (Data Over Cable System Interface Specification) signal standards or another suitable communication method. The wireless links may also use any suitable frequency band. In one example, frequency bands are used that are selected from among ranges of licensed frequency bands (e.g., 6 GHz, 11 GHz, 18 GHz, 23 GHz, 24 GHz, 28 GHz, or 38 GHz band) and unlicensed frequency bands (e.g., 900 MHz, 2.4 GHz, 5.8 GHz, 24 GHz, 38 GHz, or 60 GHz (i.e., 57-64 GHz)).

Accordingly, the communication network 104 includes links that may be formed by power lines, non-power line wired media, and wireless media. The links may occur at any point along a communication path between a backhaul node 132 and a user device 130, or between a backhaul node 132 and a distribution point 127 or aggregation point 124.

Communication among nodes 128 may occur using a variety of protocols and media. In one example, the nodes 128 may use time division multiplexing and implement one or more layers of the 7 layer open systems interconnection (OSI) model. For example, at the layer 3 ‘network’ level, the devices and software may implement switching and routing technologies, and create logical paths, known as virtual circuits, for transmitting data from node to node. Similarly, error handling, congestion control and packet sequencing can be performed at Layer 3. In one example embodiment, Layer 2 ‘data link’ activities include encoding and decoding data packets and handling errors of the ‘physical’ layer 1, along with flow control and frame synchronization. The configuration of the various communication nodes may vary. For example, the nodes coupled to power lines may include a modem that is substantially compatible with the HomePlug 1.0 or A/V standard. In various embodiments, the communications among nodes may be time division multiple access or frequency division multiple access.

### Software:

The communication network 104 may be monitored and controlled via a power line server 118 (see FIG. 1) that may be remote from the structure and physical location of the network elements. The controller of the nodes 128 describe herein may include executable program code for controlling the operation of the nodes and responding to commands. The PLS 118 may transmit any number of commands to a backhaul nodes 132 and access nodes 134 to manage the system. As will be evident to those skilled in the art, most of these commands are equally applicable for backhaul nodes 132 and access nodes 134. For ease of discussion, the description of the commands will be in the context of a node 128 (meant to include both). These commands may include altering configuration information, synchronizing the time of the node 128 with that of the PLS, controlling measurement intervals (e.g., voltage measurements), requesting measurement or data statistics, requesting the status of user device activations, rate shaping, and requesting reset or other system-level commands. Any or all of these commands may require a unique response from the node 128, which may be transmitted by the node 128 and received and stored by the PLS. The PLS may include software to transmit a command to any or all of the nodes (134 and 132) to schedule a voltage and/or current measurement at any particular time so that all of the network elements of the PLCS take the measurement(s) at the same time.

Any of the nodes described herein may include an analog to digital converter (ADC) for measuring the voltage, current, and/or other parameters of any power line 110, 114. The ADC may be located within the power line parameter sensor device 115 or within the power line communication device 138, 139, 135. The ADC Scheduler software, in conjunction with the real-time operating system, creates ADC scheduler tasks to perform ADC sampling according to configurable periods for each sample type. Each sample type corresponds with an ADC channel. The ADC Scheduler software creates a scheduling table in memory with entries for each sampling channel according to default configurations or commands received from the PLS. The table contains timer intervals for the next sample for each ADC channel, which are monitored by the ADC scheduler. Each separate measurable parameter may have an ADC measurement task. Each ADC measurement task may have configurable rates for processing, recording, and reporting for example.

An ADC measurement task may wait on a timer (set by the ADC scheduler). When the timer expires the task may retrieve all new ADC samples for that measurement type from the sample buffer, which may be one or more samples. The raw samples are converted into a measurement value. The measurement is given the timestamp of the last ADC sample used to make the measurement. The measurement may require further processing. If the measurement (or processed measurement) exceeds limit values, an alert condition may be generated. Out of limit Alerts or notifications may be transmitted to the PLS and repeated at the report rate until the measurement is back within limits. An out of limit recovery Alert may be generated (and transmitted to the PLS) when the out of limit condition is cleared (i.e., the measured value falls back within limit conditions). For example, if a current measurement greater than a predetermined value is detected—or a change in current above a predetermined delta is detected—a notification of a current surge may be transmitted.

The measurements performed by the ADC, each of which has a corresponding ADC measurement task, may include node 128 inside temperature, LV power line voltage, LV power line current, MV power line voltage, and/or MV power line current for example. MV and LV power line measurements may be accomplished via the power line parameter sensor devices 115.

As discussed, the nodes may include value limits for most of these measurements stored in memory with which the measured value may be compared. If a measurement is below a lower limit, or above an upper limit (or otherwise out of an acceptable range), the node 128 may transmit an Out-of-Limit Alert. Such alert may be received and stored by the PLS. In some instances, one or more measured values are processed to convert the measured value(s) to a standard or more conventional data value.

### Methods of Predicting a Power Line Fault

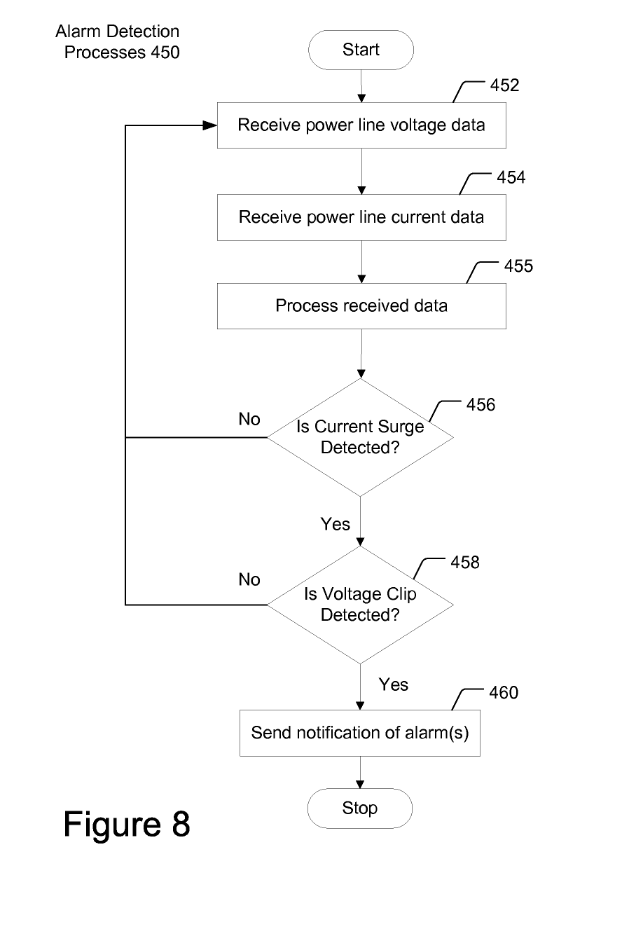

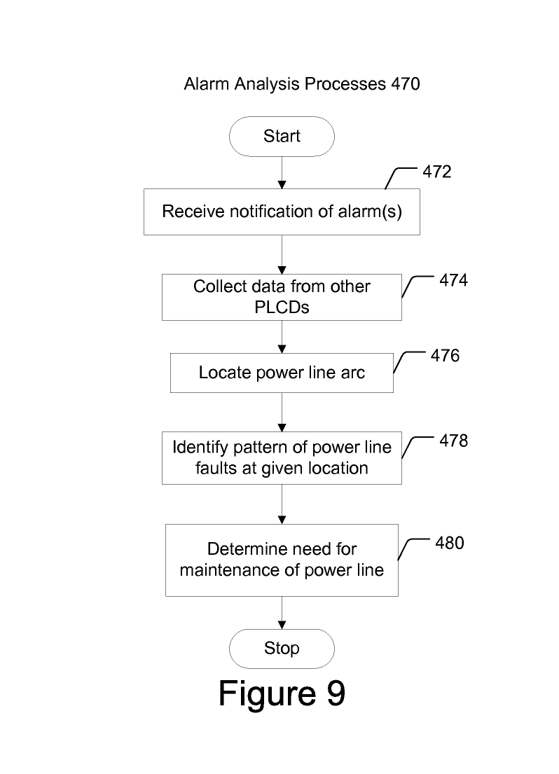

FIGS. 8 and 9 depict flow charts of a examples method according to embodiments of the present invention. FIG. 8 depicts a flow chart of processes 450 for detecting a power line arc that may be indicated by measurements of one or more power line parameters (referred to herein as “power line data”). Power line data may be collected from an underground power line sub-network, such as one of the type described above with regards to FIGS. 1, 2 and 3. In particular, each power line communication device (PLCD) 137 receiving data from power line sensors 115 monitors power line data. A given PLCD 137 may be positioned in the vicinity of a given distribution transformer 112. The PLCD 137 may receive power line current measurement data from a current sensor device 116 and power line voltage measurement data from a voltage sensor device 115. The current sensor device 116 may be coupled to the URD cable on either the upstream side and/or the downstream side of the distribution transformer. Consider an embodiment in which the current sensor is located on the upstream side of the distribution transformer, and thus, monitors MV power line current along the URD cable 110a (see FIG. 7). A voltage sensor device also may be coupled to an LV power line 114 and measure the LV voltage, which measurement may be used to compute the MV voltage (by using the turns ratio of the transformer). Thus, the voltage sensor device may monitor voltage of an MV power line and/or an LV power line. Similar or varied sensor positions may occur in the vicinities of upstream and downstream transformers.

Each PLCD 137 receives data from the sensors to which it is communicatively coupled. At step 452, a PLCD 137 receives the power line voltage data from a sensor 115. At step 454, the PLCD 137 receives the MV power line current data from a current sensor 116. One of ordinary skill will appreciate that the order in which the data is received may vary. In one embodiment, data from the current sensors may be received periodically at a rate selected so as not to miss detecting a current surge of the duration typical for a power line fault (e.g., at every 5%, 10%, or 15% of a 60 Hertz cycle). Similarly, data from the voltage sensor may be received periodically and at a rate selected so as not to miss detection of a clipped voltage. At step 455, the received data is processed, which in this example comprises determining the current data indicates a current surge has occurred (or is occurring) and, if so, determining if the current surge was initiated during a peak of the voltage (and in some instances whether the voltage was clipped). For example, processing may include, for example, comparing one or more data sets from the current sensor with a predetermined threshold current.

The predetermined threshold current may be selected to detect any abnormal current magnitude. In some embodiments, the threshold may be specifically selected to detect excessive currents such as a current surge associated with a power line fault. The degree and duration of the abnormal current may be monitored to determine whether the current pattern (as indicated by the measurements) substantially matches one or more patterns known to be a pattern of a current surge (that may be associated with an arc). In other embodiments, detecting a current surge may alternately (or additionally) comprise determining that the current increased at or above predetermined rate (delta I/delta T). Thus, at step 456, the PLCD 137 determines whether processing of the current data reveals detection of a current surge. If not, the process continues at step 452 wherein new data is received.

If a current surge is detected, the processing must determine whether the voltage was clipped at step 458 (when the surge occurred). For example, processing may include, for example, comparing one or more data sets from the voltage sensor with a predetermined minimum threshold voltage. In addition, the distribution transformer typically will shift the phase of the voltage of the LV power by about thirty degrees (relative to the voltage of the MV power line). Consequently, the peak voltage of the LV power line will not coincide with the peak voltage of the MV voltage power line. Thus, the processing may include shifting the voltage measurement of the LV power line by about thirty degrees (e.g., in time) to determine if the measured current surge coincided with the peak MV voltage. In some embodiments, instead of detecting a voltage clip, this step may simply determine whether the surge occurred (e.g., was initiated) during a voltage peak. In the present embodiment, a predetermined threshold voltage may be selected to detect a voltage clip. In some embodiments, the voltage threshold may be specifically selected to detect a peak voltage below a minimum such as a voltage clip associated with a power line fault. The degree and duration of the voltage abnormality (reduced peak) may be monitored to determine whether the voltage pattern (as indicated by the measurements) substantially matches one or more patterns known to be a peak voltage pattern (that may be associated with an arc). If not, the process continues at step 452 wherein new data is received.

If the measurements indicate that a surge occurred and that the voltage was clipped (or that the surge occurred at the peak), the PLCD 137 transmits an alarm condition notification at step 460. The notification may include the sensor data, which may be sent to the power line server 118 (or other remote computer) for further analysis and reporting. The notification may also include a time stamp and information identifying the PLCD 137 transmitting the notification, which may be used by the PLS to determine the location where the measurement were taken (and the power line and/or power line segments affected).

In various embodiments, the method steps may be performed or repeated by different devices. As described above, the PLCD may process the sensor data and detect alarm conditions. In other embodiments, the sensor devices may detect alarm conditions and report such conditions to the PLCD. In still other embodiments, the PLS may process or reprocess the sensor data and detect alarm conditions.

The sensor data collected at multiple PLCDs 137 may be sent to the power line server 118 or another processing center. In addition, notifications from multiple PLCD's may be received at the PLS (or other computer). FIG. 9 shows a flow chart of processes 470 for analyzing alarm conditions (identified by notifications) to predict a power line fault. Such processes 470 may be performed, for example, at the PLS 118 or other processing center. At step 472 an alarm condition notification is received. Various processing scenarios may be triggered in response to an alarm condition notification.

For example, an alarm indicating a clipped voltage may trigger a scenario to look for an accompanying current surge reported concurrently by the same PLCD. Similarly, an alarm indicating a current surge may trigger a scenario to look for a clipped voltage reported by the same PLCD 137 that occurred concurrently with the current surge. The presence of both conditions may signify a power line arc.

As previously described, an arc event may cause a clipped voltage in both an upstream and downstream direction (if any) relative to the specific location where the arc occurs. However, a current surge caused by the arc typically will be detected only by PLCDs 137 upstream from the arc. Consequently, if a first set of one or more PLCDs detect a current surge and another adjacent set of one or more PLCDs (adjacent on the same MV power line) do not detect the current surge, the arc may then be determined to have occurred between the two sets of PLCDs 137. More specifically, the URD cable segment connecting the transformers co-located with those PLCDs sets (i.e., the cable segment connecting adjacent transformers from those sets) may be identified as the cable in which the arc occurred. Thus, in order to determine the location of the arc, the PLS 118 collects additional data from other PLCDs taking measurements on that MV power line at step 474. More specifically, the PLS 118 may transmit a request to the PLCDs 137 connected to the same MV power line 110 as the PLCD 137 that transmitted the alarm condition notification. The request may include a request for current data during the time period identified by the alarm condition notification. In response, the PLCDs 137 retrieve the requested data from memory and transmit the data to the PLS.

Next, based on the collected information the PLS 118 determines the location of the arc at step 476. Specifically, the arc may be determined to occur in a segment connected to transformers having co-located PLCDs 137 wherein one PLCD detected a current surge (or arc) and the other PLCD 137 did not detect a current surge (or arc).

In some embodiments additional processes may be performed to determine the severity of the problem. As previously described, the current surge accompanying an arc caused by a deteriorating power line heats and evaporates the local moisture in the spot where the arc occurred. As a result, an arc may not repeat immediately. Gradually, however, the moisture builds up until another arc and an accompanying current surge occurs. At step 478 an additional process may be performed to identify a pattern of arc events over time occurring at the same URD cable segment. In particular, as the URD cable deteriorates (e.g., due to repeated arcing), the time interval between power line arcs occurring at such URD cable segment decreases. Thus, a decrease in the time between such reoccurring faults may indicate the severity of the URD cable deterioration is increasing (i.e., getting closer to a fault resulting in a power outage) and be useful for predicting adverse events locally in the power distribution system. For example, other devices may be damaged due to the reoccurring power line arc. Further, the power line itself may fail (fault) if not replaced in a timely manner. Thus, identifying a pattern may comprise determining the rate of the current surges occurring, and based on the rate of the current surges, determining an immediacy of a fault of the power line. Accordingly, at step 480 a process may be performed to determine the need for performing local maintenance in the vicinity of the deteriorating URD cable or to repair or replace the URD cable. More specifically, a predetermined number of arcs are detected in a cable within a predetermined time period may indicate an imminent fault and that the power line segment should be replaced or repaired. The predetermined number of arcs and the time period will vary based on the voltage of the power line, the moisture in the earth and other factors. For example, determining an immediacy of the fault may comprise taking a first action (e.g., perform immediate maintenance) when the rate of current surges of a power line are above a threshold and taking a second action when the rate of current surges is below the threshold (e.g., issue order to replace cable upon next occurrence of surge).

Thus, in one embodiment a system for detecting an arc in a power line carrying a voltage and a current is provided. The system may comprise a plurality of communications devices and wherein each of the plurality of communications devices is coupled to a respective sensor device. Each of the respective sensor device of each communications device may be configured to measure the current of the power line at a different location along the power line. Each of the plurality of communication devices may be configured to receive current data from its respective current sensor and to process the current data to detect a rapid increase in current that satisfies a predetermined similarity threshold of a current surge and wherein each of the plurality of communication devices is configured to transmit a notification to a remote computer upon detection of a current surge.

While the present invention has been described in the context of a underground power system, the present invention may be used to detect failing insulators, lightning arrestors, or any device or material that provides insulation (in underground or overhead power line systems).

It is to be understood that the foregoing illustrative embodiments have been provided merely for the purpose of explanation and are in no way to be construed as limiting of the invention. Words used herein are words of description and illustration, rather than words of limitation. In addition, the advantages and objectives described herein may not be realized by each and every embodiment practicing the present invention. Further, although the invention has been described herein with reference to particular structure, materials and/or embodiments, the invention is not intended to be limited to the particulars disclosed herein. Rather, the invention extends to all functionally equivalent structures, methods and uses, such as are within the scope of the appended claims. Those skilled in the art, having the benefit of the teachings of this specification, may affect numerous modifications thereto and changes may be made without departing from the scope and spirit of the invention.

What is claimed is:

1. A method of detecting an arc on a medium voltage power line forming part of a power distribution system that carries an alternating voltage and current, comprising:
receiving voltage measurement data of the alternating voltage of the medium voltage power line;
receiving current measurement data of the current of the medium voltage power line;
detecting a current surge based on received current measurement data; and
processing the voltage measurement data to determine whether the current surge initiated during a peak of the alternating voltage.

2. The method according to claim 1, further comprising upon determining that the current surge initiated during a peak voltage of the alternating voltage, transmitting a notification.

3. The method according to claim 2, wherein said transmitting comprises transmitting the notification over a medium voltage power line.

4. The method according to claim 2, wherein said transmitting comprises transmitting the notification wirelessly.

5. The method according to claim 1, wherein the voltage measurement data comprises data of a voltage measurement of a low voltage power line connected to a distribution transformer that is connected to the medium voltage power line.

6. The method according to claim 1, wherein the alternating voltage of the medium voltage power line has a period, and wherein the detected current surge extends for less than fifty percent of the period of the alternating voltage.

7. The method according to claim 1, wherein the power line comprises an underground medium voltage power line.

8. The method according to claim 1, wherein said receiving voltage measurement data and receiving current measurement data comprise receiving the voltage measurement data and the current measurement data via a data path that includes the internet.

9. The method according to claim 1, wherein said detecting is performed by a device connected to the medium voltage power line.

10. The method according to claim 1, wherein the alternating voltage of the medium voltage power line has a period, and wherein said detecting a current surge comprises determining that an increase in the current extends for less than fifty percent of the period of the alternating voltage.

11. A method of detecting an adverse event on a medium voltage power line forming part of a power distribution system and that carries an alternating voltage and current, comprising:
monitoring the alternating voltage of the medium voltage power line;
wherein the voltage includes a positive peak and a negative peak;
monitoring the current of the medium voltage power line;
detecting a current surge;
determining that the current surge begins during a peak of the voltage; and
transmitting a notification of the detection.

12. The method according to claim 11, wherein said monitoring the alternating voltage of the power line comprises measuring a voltage of a low voltage power line connected to the medium voltage power line via a distribution transformer.

13. The method according to claim 12, wherein said determining that the current surge begins during a peak of the voltage comprises time shifting voltage measurement data of the low voltage power line.

14. The method according to claim 11, wherein the alternating voltage of the medium voltage power line comprises a period, and wherein said detecting a current surge comprises determining that an increase in the current extends for less than fifty percent of the period of the alternating voltage.

15. The method according to claim 11, wherein the power line comprises an underground medium voltage power line.

16. The method according to claim 11, wherein said transmitting comprises transmitting the notification over a medium voltage power line.

17. The method according to claim 11, wherein said transmitting comprises transmitting the notification wirelessly.

18. The method according to claim 11, wherein said monitoring the current and said determining are performed by the same device.

19. The method according to claim 11, wherein said monitoring the current and said determining are performed by different devices remote from each other.

20. The method according to claim 11, further comprising determining that the current surge extends for less than a predetermined duration.

21. A method of processing data for an underground medium voltage power line cable carrying power and formed, in part, of a power line cable segment connected on a first end to a first distribution transformer and on a second end to a second distribution transformer, comprising:
receiving a first message that indicates a current surge on the medium voltage power line cable has been detected at the first transformer;
determining that a current surge on the medium voltage power line cable was not detected at the second transformer during the current surge of the first transformer; and
based on the first and second message, determining that an adverse power line event occurred on the power line cable segment.

22. The method according to claim 21, wherein the adverse power line event comprises an arc.

23. The method according to claim 21, further comprising receiving a second message sufficient for determining that the current surge initiated during a peak of a voltage of the medium voltage power line.

24. The method according to claim 21, further comprising receiving voltage data indicating that a peak of the voltage of the medium voltage power line at the first transformer and at the second transformer was clipped during at least a portion of the current surge.

25. The method according to claim 21, wherein determining that a current surge was not detected comprises not receiving a message indicating that a current surge was detected at the second transformer.

26. The method according to claim 21, wherein determining that a current surge was not detected comprises receiving a message sufficient for determining that a current surge was not detected at the second transformer.

27. The method according to claim 21, further comprising:
receiving a plurality of messages that each indicate a current surge has been measured at the first transformer; and
determining the rate of occurrence of the current surges at the first transformer;
taking a first action when the rate of occurrence of the current surges of a power line is above a threshold; and
taking a second action when the rate of occurrence of the current surges is below the threshold.

28. The method according to claim 21, wherein the current surge extends for less than a cycle of the power carried by the power line.

29. A system for detecting an arc in a power line carrying a voltage and a current, comprising:
a plurality of communications devices;
wherein each of the plurality of communications devices is coupled to a respective sensor device;
wherein the respective sensor device of each communications device is configured to measure the current of the power line at a different location along the power line;
wherein each of the plurality of communication devices is configured to receive current data from its respective current sensor and to process the current data to detect a rapid increase in current that satisfies a predetermined similarity threshold of a current surge; and
wherein each of the plurality of communication devices is configured to transmit a notification to a remote computer upon detection of a current surge.

30. The system of claim 29, further comprising a remote computer system configured to:
receive a notification from each of the plurality of communications devices; and
determine a location of an arc based on the notification.

31. The system according to claim 29, further comprising a remote computer system configured to receive voltage data and to determine whether a detected current surge has occurred during a peak of the voltage of the power line.

32. The system according to claim 29, wherein each of the plurality of communication devices is configured to determine whether a detected current surge occurs during a peak of the voltage of the power line.
